(19) United States
(12) Patent Application Publication
(10) Pub. No.: US 2009/0079471 A1
(43) Pub. Date: Mar. 26, 2009

(54) LOW POWER BUFFER CIRCUIT

(76) Inventor: Ting-Yuan Cheng, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 11/861,253

(22) Filed: Sep. 25, 2007

(51) Int. Cl. H03K 3/00

(52) U.S. Cl. 327/108

(57) ABSTRACT

A dual-output buffer circuit for providing a first reference voltage and a second reference voltage has a first buffer circuit, a second buffer circuit, a first reference voltage coupled to the first buffer circuit, a second reference voltage coupled to the second buffer circuit, and a diode circuit coupled to a first output terminal of the first buffer circuit and a second output terminal of the second buffer circuit.

### BACKGROUND OF THE INVENTION

1. Field of the Invention

The present invention relates to buffer circuits, and more particularly, to a low power buffer circuit with current re-use.

2. Description of the Prior Art

As increasing numbers of electronic products and technologies adopt digital receiving, processing, and transmitting methods, particularly in the areas of mobile communications and multimedia, analog-to-digital converters (ADC) and digital-to-analog converters (DAC) are becoming essential blocks in the electronic products. In order to provide high quality and fast conversion of analog and digital signals, ADC and DAC designers work with trade-offs, not only between quality and speed, but also power consumption, noise performance, and size.

One important component in ADCs and DACs is a buffer circuit used for providing positive and negative voltages to the ADC or DAC. Please refer to FIG. 1, which is a diagram of a first buffer circuit 110 and a second buffer circuit 120 according to the prior art. In the prior art, in order to provide both a positive reference voltage and a negative reference voltage, the first buffer circuit 110 is used to provide the positive reference voltage and the second buffer circuit 120 is used to provide the negative reference voltage. The first buffer circuit 110 comprises a first amplifier 111, a first reference voltage source 112 coupled to a negative input port of the first amplifier 111 and VSS, a P-type metal-oxide-semiconductor (PMOS) transistor 113 having a gate coupled to an output of the first amplifier 111, a source coupled to VDD, and a drain coupled to a positive input port of the first amplifier 111, and a first reference current source 114 coupled to the drain of the PMOS transistor 113 and VSS. The first buffer circuit 110 produces a first reference output VREF1 at the drain of the PMOS transistor 113. The second buffer circuit 120 comprises a second amplifier 121, a second reference voltage source 122 coupled to a positive input port of the second amplifier 121 and VSS, a PMOS transistor 123 having a gate coupled to an output of the first amplifier 121, a drain coupled to VSS, and a source coupled to a negative input port of the second amplifier 121, and a second reference current source 124 coupled to the source of the PMOS transistor 123 and VDD. The second buffer circuit 120 produces a second reference output VREF2 at the drain of the PMOS transistor 123.

Please refer to FIG. 2, which is a diagram of a first buffer circuit 210 and a second buffer circuit 220 that are realized with N-type metal-oxide-semiconductor (NMOS) transistors. The first buffer circuit 210 comprises a first amplifier 211, a first reference voltage source 212 coupled to a positive input port of the first amplifier 211 and VSS, an NMOS transistor 213 having a gate coupled to an output of the first amplifier 211, a drain coupled to VDD, and a source coupled to a negative input port of the first amplifier 211, and a first reference current source 214 coupled to the source of the NMOS transistor 213 and VSS. The first buffer circuit 210 produces a first reference output VREF1 at the source of the NMOS transistor 213. The second buffer circuit 220 comprises a second amplifier 221, a second reference voltage source 222 coupled to a negative input port of the second amplifier 221 and VSS, an NMOS transistor 223 having a gate coupled to an output of the first amplifier 221, a source coupled to VSS, and a drain coupled to a positive input port of the second amplifier 221, and a second reference current source 224 coupled to the drain of the NMOS transistor 223 and VDD. The second buffer circuit 220 produces a second reference output VREF2 at the drain of the NMOS transistor 223.

To provide the positive reference voltage and the negative reference voltage, the prior art utilizes the first buffer circuits 110, 210 and the second buffer circuits 120, 220. However, the buffer circuits according to the prior art have disadvantages of long settling time and high power consumption.

### SUMMARY OF THE INVENTION

According to the present invention, a dual-output buffer circuit for providing a first reference voltage and a second reference voltage comprises a first buffer circuit comprising a first input terminal, a first output terminal, and a first power terminal for providing the first reference voltage at the first output terminal. The first power terminal is coupled to a first power supply voltage. The dual-output buffer circuit further comprises a second buffer circuit comprising a second input terminal, a second output terminal, and a second power terminal for providing the second reference voltage at the second output terminal. The second power terminal is coupled to a second power supply voltage. The dual-output buffer circuit further comprises a first reference voltage supply coupled to the first input terminal and the second power supply voltage, and a second reference voltage supply coupled to the second input terminal and the second power supply voltage. The dual-output buffer circuit further comprises a diode circuit having a first terminal coupled to the first output terminal of the first buffer circuit and a second terminal coupled to the second output terminal of the second buffer circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of PMOS buffer circuits according to the prior art.

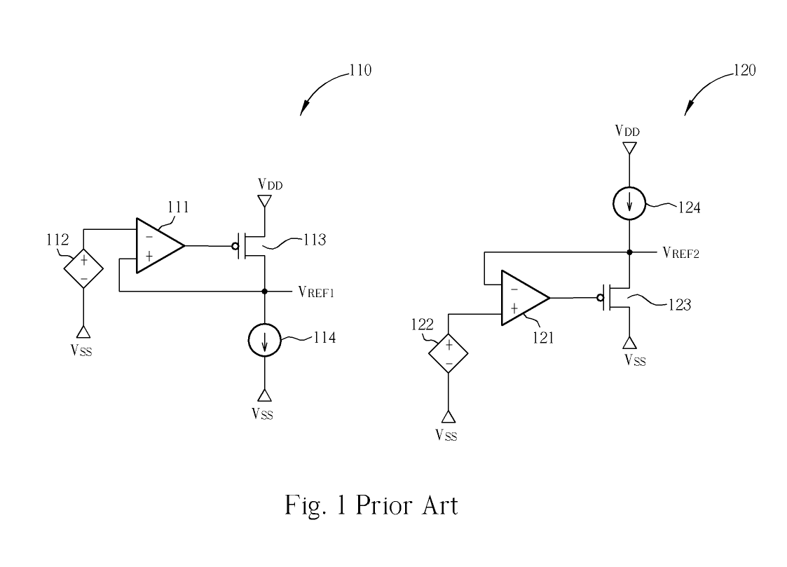

FIG. 2 is a diagram of NMOS buffer circuits according to the prior art.

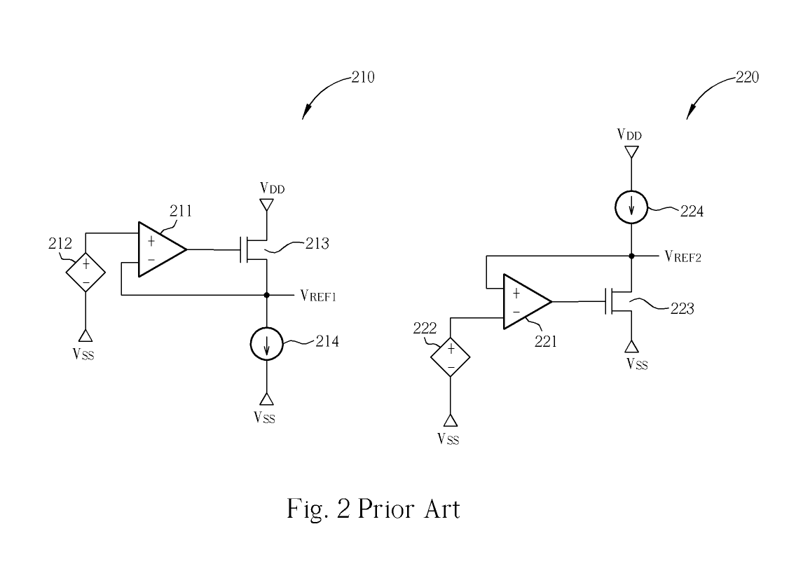

FIG. 3 is a diagram of a dual-output buffer circuit according to the present invention.

FIG. 4 is a diagram of a second embodiment of the dual-output buffer circuit according to the present invention.

### DETAILED DESCRIPTION

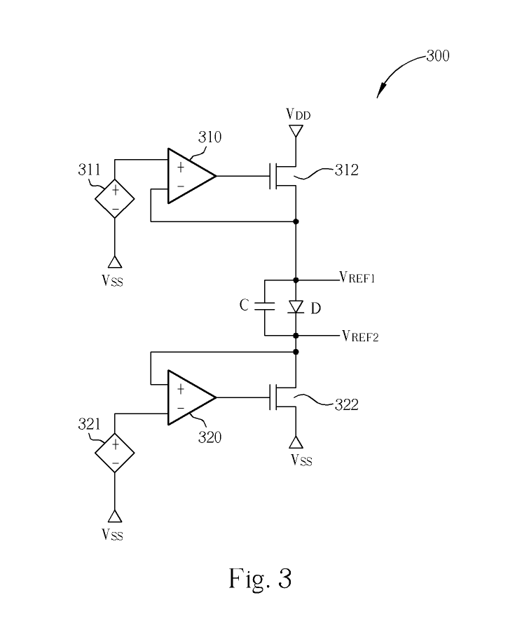

Please refer to FIG. 3, which is a diagram of a dual-output buffer circuit 300 according to the present invention. The dual-output buffer circuit 300 is powered from VDD to VSS. The dual-output buffer circuit 300 comprises a first amplifier 310, a first reference voltage source 311 coupled to a positive input port of the first amplifier 310 and VSS, a first N-type metal-oxide-semiconductor (NMOS) transistor 312 having a gate coupled to an output of the first amplifier 310, a drain coupled to VDD, and a source coupled to a negative input port of the first amplifier 310. The dual-output buffer circuit 300 further comprises a second amplifier 320, a second reference voltage source 321 coupled to a negative input port of the second amplifier 320 and VSS, a second NMOS transistor 322 having a gate coupled to an output of the second amplifier 320, a source coupled to VSS, and a drain coupled to a positive input of the second amplifier 320. The dual-output buffer circuit 300 further comprises a diode D having a first terminal coupled to the source of the first NMOS transistor 312 and a second terminal coupled to the drain of the second NMOS transistor 322, and a capacitor C coupled between the source of the first NMOS transistor 312 and the drain of the second NMOS transistor 322. A first reference voltage VREF1 is taken at the source of the first NMOS transistor 312 or the first terminal of the diode D, and a second reference voltage VREF2 is taken at the drain of the second NMOS transistor 322 or the second terminal of the diode D.

Of course, numerous modifications could be made to the dual-output buffer circuit 300 shown in FIG. 3. For instance, the first NMOS transistor 312 could be replaced with a cascode of a plurality of NMOS transistors, and the second NMOS transistor 322 could also be replaced with a cascode of a plurality of NMOS transistors. Also, in the embodiment shown in FIG. 3, the first NMOS transistor 312 and the second NMOS transistor 322 are both NMOS transistors. The dual-output buffer circuit 300 could be modified to use PMOS transistors instead of the first NMOS transistor 312 and the second NMOS transistor 322, or the cascodes of NMOS transistors mentioned above. Further, the capacitor C is not a necessary component for enabling the dual-output buffer circuit 300, and could be removed. Finally, the embodiment shown in FIG. 3 is realized in MOS technology, but could also be realized in bipolar or other transistor technologies. In general, any dual-output buffer circuit having two buffer circuits whose outputs are coupled through a diode falls within the concept of the present invention.

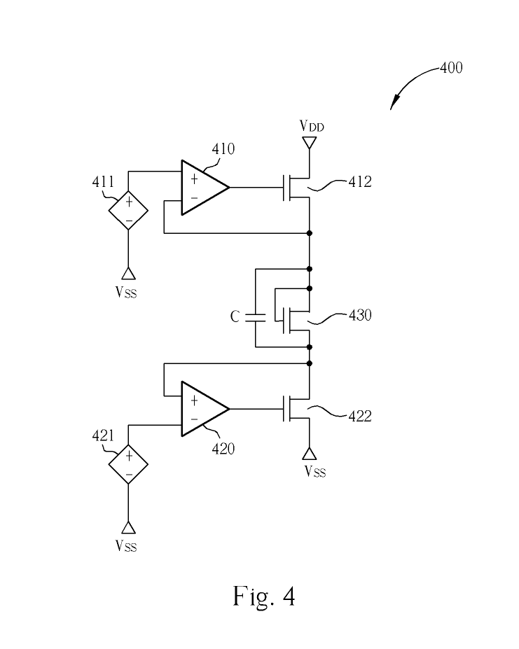

Please refer to FIG. 4, which is a diagram of a second embodiment of the present invention dual-output buffer circuit 400. The dual-output buffer circuit 400 is powered from VDD to VSS. The dual-output buffer circuit 400 comprises a first amplifier 410, a first reference voltage source 411 coupled to a positive input port of the first amplifier 410 and VSS, a first NMOS transistor 412 having a gate coupled to an output of the first amplifier 410, a drain coupled to VDD, and a source coupled to a negative input port of the first amplifier 410. The dual-output buffer circuit 400 further comprises a second amplifier 420, a second reference voltage source 421 coupled to a negative input port of the second amplifier 420 and VSS, a second NMOS transistor 422 having a gate coupled to an output of the second amplifier 420, a source coupled to VSS, and a drain coupled to a positive input of the second amplifier 420. The dual-output buffer circuit 400 further comprises a third NMOS transistor 430 having a gate and a drain both coupled to the source of the first NMOS transistor 412, and a source coupled to the drain of the second NMOS transistor 412, and a capacitor C coupled between the source of the first NMOS transistor 412 and the drain of the second NMOS transistor 422. The third NMOS transistor 430 can be considered a “diode-connected transistor.” A first reference voltage VREF1 is taken at the source of the first NMOS transistor 412 or the gate or the drain of the third NMOS transistor 430, and a second reference voltage VREF2 is taken at the drain of the second NMOS transistor 422 or the source of the third NMOS transistor 430.

Like mentioned above, various modifications could be made to the dual-output buffer circuit 400 shown in FIG. 4. For instance, the first NMOS transistor 412 could be replaced with a cascode of a plurality of NMOS transistors, and the second NMOS transistor 422 could also be replaced with a cascode of a plurality of NMOS transistors. Also, in the embodiment shown in FIG. 4, the first NMOS transistor 412 and the second NMOS transistor 422 are both NMOS transistors. The dual-output buffer circuit 400 could be modified to use PMOS transistors instead of the first NMOS transistor 412 and the second NMOS transistor 422, or the cascodes of NMOS transistors mentioned above. Further, the capacitor C is not a necessary component for enabling the dual-output buffer circuit 400, and could be removed. Finally, the embodiment shown in FIG. 4 is realized in MOS technology, but could also be realized in bipolar or other transistor technologies. In general, any dual-output buffer circuit having two buffer circuits whose outputs are coupled through a diode-connected transistor falls within the concept of the present invention.

As shown in FIGS. 3 and 4, the dual-output buffer circuits 300, 400 utilize the diode D and the diode-connected transistor 430, respectively, to set up a voltage difference between the first reference voltage VREF1 and the second reference voltage VREF2. Further, by cascoding the first buffer circuit 310, 410 and the second buffer circuit 320, 420, the present invention dual-output buffer circuits 300, 400 do not require the current sources of the prior art, but instead generate a “current re-use” effect, which saves power compared to the prior art. The present invention also has a faster settling time and lower impedance compared to the buffer circuits of the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dual-output buffer circuit for providing a first reference voltage and a second reference voltage comprising:
a first buffer circuit comprising a first input terminal, a first output terminal, and a first power terminal for providing the first reference voltage at the first output terminal, wherein the first power terminal is coupled to a first power supply voltage;
a second buffer circuit comprising a second input terminal, a second output terminal, and a second power terminal for providing the second reference voltage at the second output terminal, wherein the second power terminal is coupled to a second power supply voltage;
a first reference voltage coupled to the first input terminal and the second power supply voltage;
a second reference voltage coupled to the second input terminal and the second power supply voltage; and
a diode circuit having a first terminal coupled to the first output terminal of the first buffer circuit and a second terminal coupled to the second output terminal of the second buffer circuit.

2. The dual-output buffer circuit of claim 1, wherein the first buffer circuit further comprises:
a first transistor having a first transistor terminal coupled to the first power terminal and a second transistor terminal coupled to the first output terminal; and
an amplifier circuit having a first input coupled to the first input terminal, a second input coupled to the first output terminal, and an output coupled to a control node of the first transistor.

3. The dual-output buffer circuit of claim 2, wherein the first transistor is a metal-oxide-semiconductor (MOS) transistor, and the control node of the first transistor is a gate of the first transistor.

4. The dual-output buffer circuit of claim 2, wherein the second buffer circuit further comprises:
a second transistor having a first transistor terminal coupled to the second power terminal and a second transistor terminal coupled to the second output terminal; and
an amplifier circuit having a first input coupled to the second input terminal, a second input coupled to the second output terminal, and an output coupled to a control node of the second transistor.

5. The dual-output buffer circuit of claim 4, wherein the second transistor is a metal-oxide-semiconductor (MOS) transistor, and the control node of the second transistor is a gate of the second transistor.

6. The dual-output buffer circuit of claim 5, wherein the first transistor and the second transistor are both P-type MOS (PMOS) transistors.

7. The dual-output buffer circuit of claim 5, wherein the first transistor and the second transistor are both N-type MOS (NMOS) transistors.

8. The dual-output buffer circuit of claim 4, wherein the diode circuit comprises a metal-oxide-semiconductor (MOS) transistor coupled between the first output terminal and the second output terminal.

9. The dual-output buffer circuit of claim 8, wherein the diode circuit further comprises a capacitor coupled between the first output terminal and the second output terminal.

10. The dual-output buffer circuit of claim 4, wherein the diode circuit comprises a bipolar junction transistor (BJT) coupled between the first output terminal and the second output terminal.

11. The dual-output buffer circuit of claim 10, wherein the diode circuit further comprises a capacitor coupled between the first output terminal and the second output terminal.

12. The dual-output buffer circuit of claim 4, wherein the diode circuit comprises a diode coupled between the first output terminal and the second output terminal.

13. The dual-output buffer circuit of claim 12, wherein the diode circuit further comprises a capacitor coupled between the first output terminal and the second output terminal.

14. The dual-output buffer circuit of claim 4, wherein the first buffer circuit further comprises a third transistor cascoded with the first transistor and coupled to the first power terminal.

15. The dual-output buffer circuit of claim 4, wherein the second buffer circuit further comprises a fourth transistor cascoded with the second transistor and coupled to the second power terminal.
